(19) United States
(12) Patent Application Publication
(10) Pub. No.: US 2015/0357392 A1
(43) Pub. Date: Dec. 10, 2015

(54) ORGANIC LIGHT-EMITTING DIODE (OLED) DISPLAY

(71) Applicant: Samsung Display Co., Ltd., Yongin-City (KR)

(72) Inventor: Chun-Gi You, Yongin-City (KR)

(21) Appl. No.: 14/472,054

(22) Filed: Aug. 28, 2014

(30) Foreign Application Priority Data
Jun. 10, 2014 (KR) 10-2014-0070274

(51) Int. Cl. H01L 27/32; H01L 51/52

(52) U.S. Cl. CPC H01L 27/3269; H01L 51/5253; H01L 51/5262; H01L 27/3246; H01L 27/3248; H01L 51/5271; H01L 27/3227; H01L 27/3239

(57) ABSTRACT

An organic light-emitting diode (OLED) display is disclosed. In one aspect, the OLED display includes a base substrate and a display unit formed on a first surface of the base substrate, and including i) an active region having an OLED configured to emit light and ii) a dummy region formed in an outer portion of the active region. The OLED display further includes an encapsulation substrate encapsulating the display unit and a photo sensor mounted in an outer portion of the dummy region and configured to measure intensity of the light emitted from the OLED. The OLED includes a pixel electrode, an opposite electrode facing the pixel electrode and extending over the dummy region, and an emission layer interposed between the pixel electrode and the opposite electrode. The dummy region includes a light path configured to guide light reflected from the opposite electrode to the photo sensor.

### INCORPORATION BY REFERENCE TO ANY PRIORITY APPLICATIONS

This application claims the benefit of Korean Patent Application No. 10-2014-0070274, filed on Jun. 10, 2014, in the Korean Intellectual Property Office, the disclosure of which is incorporated herein in its entirety by reference.

### BACKGROUND

1. Field

The described technology generally relates to an organic light-emitting diode (OLED) display.

2. Description of the Related Technology

In general, an OLED display has a panel having a structure in which an encapsulation substrate covers a base substrate on which a display unit is formed, and an area around the display unit between the two substrates is sealed by using a sealant. The display unit has a thin film transistor and an OLED, and when the TFT is driven, the OLED emits light such that an image is realized.

### SUMMARY OF CERTAIN INVENTIVE ASPECTS

One inventive aspect is an OLED display.

Another aspect is an OLED display which includes a base substrate; a display unit formed on one surface of the base substrate, and including an active region having an organic light-emitting device that emits light, and a dummy region that is an outer region of the active region; an encapsulation substrate for encapsulating the display unit between the base substrate and the encapsulation substrate; and a photo sensor mounted in an outer region of the dummy region, and measuring intensity of the light emitted from the organic light-emitting device, wherein the organic light-emitting device includes a pixel electrode, an opposite electrode facing the pixel electrode and extending over the dummy region, and an emission layer interposed between the pixel electrode and the opposite electrode, and wherein a light path is established in the dummy region, and light reflected from the opposite electrode is guided to the photo sensor via the light path.

The opposite electrode at the light path established in the dummy region may directly contact the base substrate, without having an intermediate layer interposed therebetween.

An insulating layer may be interposed between the opposite electrode and the base substrate such that the opposite electrode may protrude toward the encapsulation substrate and thus an embossed zone may be further arranged in the light path established in the dummy region.

A pixel-defining layer for defining a unit pixel region of the organic light-emitting device may be arranged in the active region, and the insulating layer may be formed from the same layer as the pixel-defining layer.

A thin film transistor that is connected to the organic light-emitting device may be further arranged in the active region, and the thin film transistor may include an active layer, a gate electrode, a source electrode, and a drain electrode that are stacked on the one surface of the base substrate.

In the active region, the drain electrode may be connected to the pixel electrode by having a planarization layer interposed therebetween, and the pixel electrode, and the planarization layer may not be formed in the light path established in the dummy region.

The photo sensor may be mounted at a top surface, a bottom surface, or a side surface of an end of the base substrate.

A plurality of the photo sensors may be formed at a plurality of positions on the base substrate.

A reflective layer may be formed on another surface of the base substrate. The light that is emitted from the organic light-emitting device may be emitted toward the encapsulation substrate such that an image may be realized.

Another aspect is an organic light-emitting diode (OLED) display comprising: a base substrate; a display unit formed on a first surface of the base substrate, and comprising i) an active region having an OLED configured to emit light and ii) a dummy region formed in an outer portion of the active region; an encapsulation substrate encapsulating the display unit; and a photo sensor mounted in an outer portion of the dummy region and configured to measure intensity of the light emitted from the OLED, wherein the OLED comprises a pixel electrode, an opposite electrode facing the pixel electrode and extending over the dummy region, and an emission layer interposed between the pixel electrode and the opposite electrode, and wherein the dummy region comprises a light path configured to guide light reflected from the opposite electrode to the photo sensor.

In the above display, a portion of the opposite electrode formed in the dummy region directly contacts the base substrate. The above display further comprises an insulating layer interposed between the opposite electrode and the base substrate. In the above display, the opposite electrode extends toward the encapsulation substrate so as to form an embossed zone in the light path of the dummy region. In the above display, a portion of the opposite electrode formed in the embossed zone does not contact the base substrate. In the above display, the insulating layer formed in the dummy region is discontinuous. The above display further comprises a pixel-defining layer defining a unit pixel region of the OLED and formed in the active region, wherein the insulating layer and the pixel-defining layer are formed from the same layer.

In the above display further comprises a thin film transistor electrically connected to the OLED and formed in the active region, wherein the thin film transistor comprises an active layer, a gate electrode, a source electrode, and a drain electrode that are stacked on the first surface of the base substrate. In the above display, in the active region, the drain electrode is connected to the pixel electrode by having a planarization layer interposed therebetween, and wherein the pixel electrode and the planarization layer are not formed in the light path formed in the dummy region. In the above display, the photo sensor is mounted at a top surface, a bottom surface, or a side surface of an end of the base substrate. In the above display, a plurality of the photo sensors are formed at a plurality of positions on the base substrate. The above display further comprises a reflective layer formed on a second surface of the base substrate, wherein the first and second surfaces are opposing each other. In the above display, the OLED is configured to emit the light toward the encapsulation substrate so as to display an image.

Another aspect is an organic light-emitting diode (OLED) display comprising: a substrate; a display unit formed on a first surface of the substrate, and comprising i) an active region having an OLED configured to emit light and ii) a dummy region formed in an outer portion of the active region; and a photo sensor mounted in an outer portion of the dummy region and configured to measure intensity of the light emitted from the OLED, wherein the OLED comprises an electrode extending over the dummy region, and wherein the dummy region comprises a light path configured to guide light reflected from the electrode to the photo sensor.

In the above display, a first portion of the electrode formed in the dummy region directly contacts the substrate. The above display further comprises an insulating layer interposed between the electrode and the substrate, wherein a portion of the insulating layer is formed in the dummy region. In the above display, the portion of the insulating layer is discontinuous. In the above display, a second portion of the electrode formed in the dummy region does not contact the substrate. In the above display, a plurality of the photo sensors are formed at a plurality of positions on the substrate. The above display further comprises a reflective layer formed on a second surface of the substrate, wherein the first and second surfaces are opposing each other.

### BRIEF DESCRIPTION OF THE DRAWINGS

FIG. 1 is a plan view of an OLED display according to an embodiment

FIG. 2 is a side view of the OLED display shown in FIG. 1.

FIG. 3 is a cross-sectional view of the OLED display of FIG. 1, taken along a line III-III.

FIG. 4 illustrates an OLED display according to another embodiment.

FIGS. 5 and 6 illustrate examples of a mounting position of a photo sensor.

### DETAILED DESCRIPTION OF CERTAIN INVENTIVE EMBODIMENTS

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present description.

In the accompanying drawings, those components that are the same or are in correspondence are rendered the same reference numeral regardless of the figure number, and redundant explanations are omitted.

Throughout the specification, a singular form may include plural forms, unless there is a particular description contrary thereto.

Throughout the specification, it will be further understood that the terms “comprises” and/or “comprising” used herein specify the presence of stated features or components, but do not preclude the presence or addition of one or more other features or components.

Throughout the specification, it will be understood that when a layer, region, or component is referred to as being “formed on,” another layer, region, or component, it can be directly or indirectly formed on the other layer, region, or component. That is, for example, intervening layers, regions, or components may be present.

In the drawings, for convenience of description, the thicknesses or sizes of elements are exaggerated for clarity, but one or more embodiments of the present invention are not limited thereto.

Also, it should also be noted that in some alternative implementations, the steps of all methods described herein may occur out of the order. For example, two steps illustrated in succession may in fact be executed substantially concurrently or the two steps may sometimes be executed in the reverse order.

As used herein, the term “and/or” includes any and all combinations of one or more of the associated listed items. In this disclosure, the term “substantially” includes the meanings of completely, almost completely or to any significant degree under some applications and in accordance with those skilled in the art. Moreover, “formed on” can also mean “formed over.” The term “connected” includes an electrical connection.

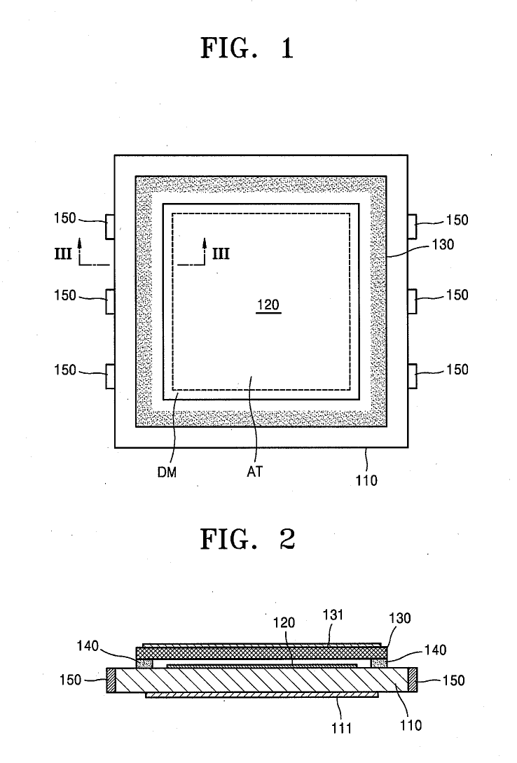

FIGS. 1 and 2 are a plan view and a side view of an OLED display according to an embodiment.

As illustrated, in the present embodiment, the OLED display includes a base substrate 110 that is formed of a glass material, a display unit 120 that is formed on the base substrate 110 and realizes an image, an encapsulation substrate 130 that encapsulates the display unit 120 between the base substrate 110 and the encapsulation substrate 130 by interposing a sealant 140 therebetween, or the like.

In the present embodiment, the OLED display is a top-emission type where an image is realized toward the encapsulation substrate 130, a polarizing film 131 is attached on an outer surface of the encapsulation substrate 130, and a reflective layer 111 is formed on an outer surface of the base substrate 110. The reflective layer 111 may also perform a function of heat dissipation.

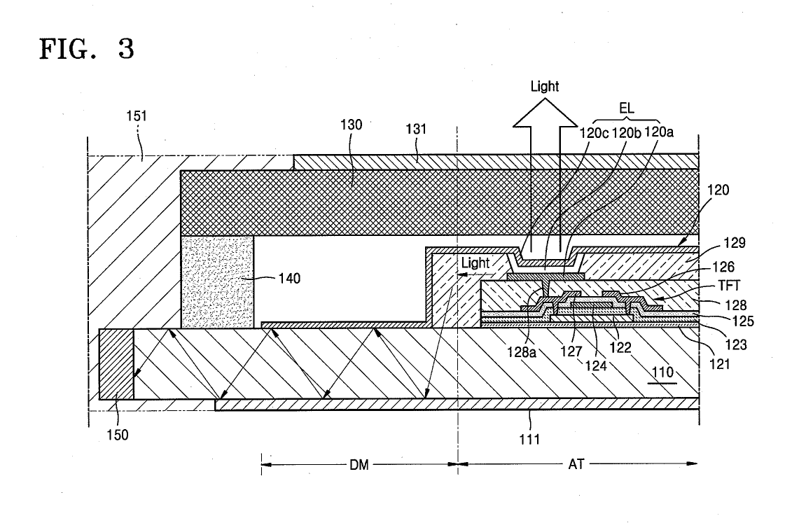

The OLED display includes a plurality of photo sensors 150 that are mounted at edges of the base substrate 110 so as to measure intensity of light that is emitted from each of adjacent pixels in the display unit 120. That is, when the display unit 120 realizes an image, emission occurs in an OLED EL (refer to FIG. 3) of each of pixels in the display unit 120, and here, the photo sensors 150 measure the intensity of light from each of the adjacent pixels and thus sense whether light with desired intensity is emitted. In some embodiments, the intensity of light is monitored to compensate for an image sticking phenomenon that occurs due to local deterioration of a pixel.

For example, when a general image is realized, all pixels of the display unit 120 repeat on or off in turn so that rapid deterioration of a specific part hardly occurs, but, if a logo of a broadcasting company or a program is continuously displayed on a specific portion of a screen, pixels of the specific portion have to remain an emission status for a long time such that deterioration of the pixels accelerate, compared to pixels of other portions, and an image sticking phenomenon occurs after screen conversion. Therefore, if a specific pixel is continuously used, emission efficiency of the pixel deteriorates such that the pixel emits light with intensity lower than a desired level, becomes dim, compared to adjacent pixels, and thus looks as image sticking to a user.

In some embodiments, in order to solve the problem, the photo sensors 150 are mounted along the edges of the display unit 120 where the logo is mainly displayed. Each of the photo sensors 150 measures intensity of light at a corresponding position, and when a measured value does not reach set intensity of light, a set value is increased to compensate for insufficient intensity of light, so that image sticking is solved. In the present embodiment, 6 photo sensors 150 are mounted, but the number and positions of the photo sensors 150 may vary depending on specific applications.

In the present embodiment, an opposite electrode 120c (refer to FIG. 3) that is arranged at the display unit 120 functions to establish a light path to the photo sensor 150. This will be described with reference to an inner structure of the display unit 120 shown in FIG. 3.

As illustrated in FIG. 3, the display unit 120 has an active region AT where an image is realized, and a dummy region DM that is an outer portion of the active region AT. The dummy region DM does not have an OLED EL where emission occurs, and is not directly related to emission of an image. However, the dummy region DM protects the active region AT against moisture or static electricity. Also, since light that is emitted from the OLED EL of the active region AT travels to the photo sensor 150 via the dummy region DM, the dummy region DM of the base substrate 110 corresponds to a light path toward the photo sensor 150.

The active region AT includes the OLED EL having a structure where a pixel electrode 120a, an emission layer 120b, and the opposite electrode 120c are sequentially stacked, and a thin film transistor TFT that is connected to the pixel electrode 120a of the organic light-emitting device EL.

The thin film transistor TFT includes an active layer 122, a gate electrode 124, a source electrode 126, and a drain electrode 127. A gate insulating layer 123 is interposed between the gate electrode 124 and the active layer 122 for insulation between the gate electrode 124 and the active layer 122.

The active layer 122 may be arranged on a buffer layer 121. The active layer 122 may be formed while containing various materials. In an embodiment, the active layer 122 contains an inorganic semiconductor material such as amorphous silicon or crystalline silicon. In another embodiment, the active layer 122 contains an oxide semiconductor. In another embodiment, the active layer 122 contains an organic semiconductor material.

The gate insulating layer 123 is arranged on the buffer layer 121 and thus covers the active layer 122, and the gate electrode 124 is formed on the gate insulating layer 123.

An interlayer insulating layer 125 is formed on the gate insulating layer 123 so as to cover the gate electrode 124, and the source electrode 126 and the drain electrode 127 are formed on the interlayer insulating layer 125 and are connected to the active layer 122.

A planarization layer 128 that covers the thin film transistor TFT is formed on the interlayer insulating layer 125. The planarization layer 128 may be formed of an inorganic material and/or an organic material.

The OLED EL is disposed on the planarization layer 128 and, as described above, the OLED EL includes the pixel electrode 120a, the emission layer 120b, and the opposite electrode 120c. A pixel-defining layer 129 is disposed on the planarization layer 128 and the pixel electrode 120a, and defines a unit pixel region.

The emission layer 120b may be a single layer or a composite layer where a hole injection layer, a hole transport layer, an electron transport layer, or an electron injection layer are formed above or below the emission layer 120b.

The pixel electrode 120a is disposed above the planarization layer 128 and is electrically connected to the drain electrode 127 of the thin film transistor TFT via a through hole 128a that penetrates through the planarization layer 128.

The pixel electrode 120a may function as an anode electrode, and the opposite electrode 120c may function as a cathode electrode. However, one or more embodiments are not limited thereto, thus, polarities of the pixel electrode 120a and the opposite electrode 120c may be switched.

The pixel-defining layer 129 has an opening that exposes the pixel electrode 120a, and thus defines a pixel region of the organic light-emitting device EL. In the present embodiment, only one opening is illustrated. However, the pixel-defining layer 129 may have a plurality of openings, and the pixel electrode 120a, the emission layer 120b, and the opposite electrode 120c may be sequentially stacked in each of the openings and may emit light.

When the openings are formed, the OLED display may include a plurality of the organic light-emitting devices EL. A plurality of pixels may be arranged in the OLEDs EL, respectively, and may realize red light, green light, blue light, or white light. Alternatively, the emission layer 120b may be commonly formed while extending over an entire portion of the planarization layer 128, regardless of positions of the pixels. Here, the emission layer 120b may have a structure in which layers that include emission materials for emitting red light, green light, and blue light may be vertically stacked or the emission materials may be mixed. A combination of other colors may also be possible, provided that the combination of other colors may emit white light. Also, the emission layer 120b may further include a color conversion layer or a color filter that converts the emitted white light into a predetermined color.

The opposite electrode 120c of the OLED EL faces the pixel electrode 120a by having the emission layer 120b formed therebetween in the active region AT, and a side of the opposite electrode 120c extends over the dummy region DM. Due to the extending opposite electrode 120c, a smooth light path toward the photo sensor 150 is formed in the dummy region DM. That is, when light is emitted toward the encapsulation substrate 130 from the OLED EL so as to realize an image, a portion of the light spreads out and thus travels toward the photo sensor 150 along the base substrate 110. Here, when the opposite electrode 120c that is formed of metal blocks the light toward the photo sensor 150 so as to prevent the light from deviating, the base substrate 110 that is formed of glass functions as a light guide plate, so that the smooth light path toward the photo sensor 150 is formed. That is, since the reflective layer 111 that is formed on the outer surface of the base substrate 110 prevents deviation of the light, if the opposite electrode 120c blocks an inner surface of the base substrate 110, the base substrate 110 may function as the light guide plate, so that the light may reach the photo sensor 150 while the deviation of the light is minimized. In particular, since the opposite electrode 120c in the dummy region DM directly contacts the base substrate 110 without an intermediate layer, a chance that the light may deviate from the light path is very low. Thus, since the light may reach the photo sensor 150 while the deviation of the light from the OLED EL is significantly decreased, accuracy in measuring intensity of the light may be enhanced. For example, if the planarization layer 128 in the active region AT, or the pixel electrode 120a are formed in the dummy region DM and thus are interposed between the base substrate 110 and the opposite electrode 120c, there is a high chance that the light may not reach the photo sensor 150 but deviates via the planarization layer 128 or of the pixel electrode 120a. However, in the present embodiment, an intermediate layer via which the light may deviate is not formed in the dummy region DM, so that measurement of the intensity of light may be accurately performed. A guide member 151 fixes the photo sensor 150 to a side surface of the base substrate 110, and at an end of the base substrate 110, a portion of the guide member 151 may function as a light guide that reflects the light into the base substrate 110. Accordingly, since deterioration of a corresponding pixel may be sensed and insufficient intensity of light may be compensated for, based on the intensity of light that is accurately measured, an image sticking problem on a screen may be efficiently solved.

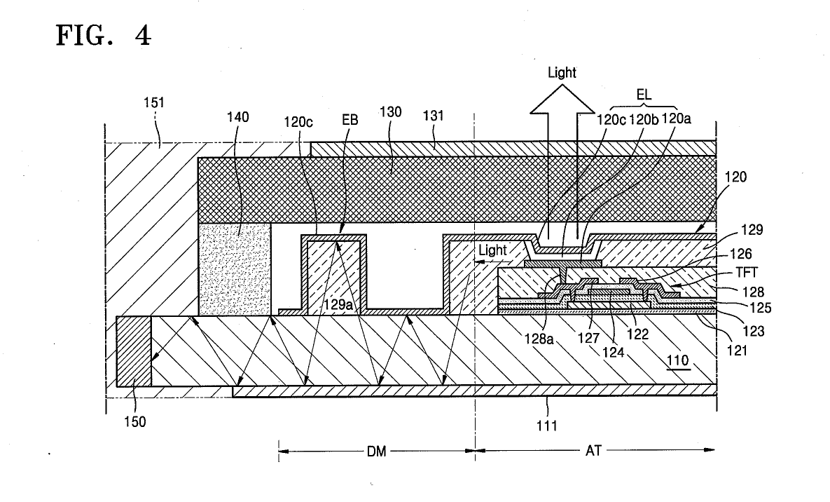

FIG. 4 illustrates an OLED display according to another embodiment.

Compared to the previous embodiment, in the present embodiment, an embossed zone EB that is embossed by an insulating layer 129a is further formed in a region between the base substrate 110 and the opposite electrode 120c in the dummy region DM. The insulating layer 129a may be formed from the same layer as the pixel-defining layer 129 in the active region AT. As described above, when the embossed zone EB is formed in the middle of a light path, a direction of light toward the photo sensor 150 is adjusted while the light passes grooves of the embossed zone EB. That is, as the light passes the grooves of the embossed zone EB, the direction of the light toward the photo sensor 150 may be further accurately focused. Thus, in order to focus the light to an accurate position of the photo sensor 150, the embossed zone EB may be formed in the dummy region DM.

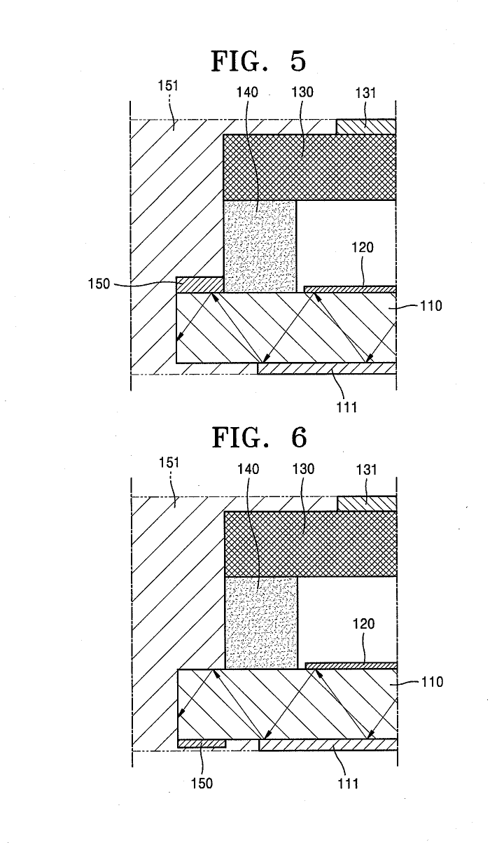

In some embodiments, the photo sensor 150 is mounted at the end of the base substrate 110, but unlike to the embodiment, as illustrated in FIG. 5, the photo sensor 150 may be mounted at a top surface of the end of the base substrate 110, or as illustrated in FIG. 6, the photo sensor 150 may be mounted at a bottom surface of the end of the base substrate 110. That is, the photo sensor 150 may be mounted at the top surface, the bottom surface, or the side surface of the base substrate 110, and if it is required to adjust a light path according to a change in an installation position, as illustrated in FIG. 4, the embossed zone EB may be formed to control the light to be focused to the photo sensor 150.

As described above, according to at least one of the disclosed embodiments, measurement accuracy of the photo sensor that measures intensity of light of each part of the display unit increases, thus, even when a region having an image sticking phenomenon occurs in the display unit, the intensity of light may be accurately compensated for by using the photo sensor, so that the image sticking may be efficiently offset.

It should be understood that the exemplary embodiments described therein should be considered in a descriptive sense only and not for purposes of limitation. Descriptions of features or aspects within each embodiment should typically be considered as available for other similar features or aspects in other embodiments.

While the inventive technology has been described with reference to the figures, it will be understood by those of ordinary skill in the art that various changes in form and details may be made therein without departing from the spirit and scope of the present invention as defined by the following claims.

What is claimed is:

1. An organic light-emitting diode (OLED) display comprising:
a base substrate;
a display unit formed on a first surface of the base substrate, and comprising i) an active region having an OLED configured to emit light and ii) a dummy region formed in an outer portion of the active region;
an encapsulation substrate encapsulating the display unit; and
a photo sensor mounted in an outer portion of the dummy region and configured to measure intensity of the light emitted from the OLED,
wherein the OLED comprises a pixel electrode, an opposite electrode facing the pixel electrode and extending over the dummy region, and an emission layer interposed between the pixel electrode and the opposite electrode, and
wherein the dummy region comprises a light path configured to guide light reflected from the opposite electrode to the photo sensor.

2. The OLED display of claim 1, wherein a portion of the opposite electrode formed in the dummy region directly contacts the base substrate.

3. The OLED display of claim 2, further comprising an insulating layer interposed between the opposite electrode and the base substrate.

4. The OLED display of claim 3, wherein the opposite electrode extends toward the encapsulation substrate so as to form an embossed zone in the light path of the dummy region.

5. The OLED display of claim 4, wherein a portion of the opposite electrode formed in the embossed zone does not contact the base substrate.

6. The OLED display of claim 3, wherein the insulating layer formed in the dummy region is discontinuous.

7. The OLED display of claim 3, further comprising a pixel-defining layer defining a unit pixel region of the OLED and formed in the active region, wherein the insulating layer and the pixel-defining layer are formed from the same layer.

8. The OLED display of claim 1, further comprising a thin film transistor electrically connected to the OLED and formed in the active region, wherein the thin film transistor comprises an active layer, a gate electrode, a source electrode, and a drain electrode that are stacked on the first surface of the base substrate.

9. The OLED display of claim 8, wherein, in the active region, the drain electrode is connected to the pixel electrode by having a planarization layer interposed therebetween, and wherein the pixel electrode and the planarization layer are not formed in the light path formed in the dummy region.

10. The OLED display of claim 1, wherein the photo sensor is mounted at a top surface, a bottom surface, or a side surface of an end of the base substrate.

11. The OLED display of claim 10, wherein a plurality of the photo sensors are formed at a plurality of positions on the base substrate.

12. The OLED display of claim 1, further comprising a reflective layer formed on a second surface of the base substrate, wherein the first and second surfaces are opposing each other.

13. The OLED display of claim 1, wherein the OLED is configured to emit the light toward the encapsulation substrate so as to display an image.

14. An organic light-emitting diode (OLED) display comprising:
a substrate;
a display unit formed on a first surface of the substrate, and comprising i) an active region having an OLED configured to emit light and ii) a dummy region formed in an outer portion of the active region; and
a photo sensor mounted in an outer portion of the dummy region and configured to measure intensity of the light emitted from the OLED,
wherein the OLED comprises an electrode extending over the dummy region, and wherein the dummy region comprises a light path configured to guide light reflected from the electrode to the photo sensor.

15. The OLED display of claim 14, wherein a first portion of the electrode formed in the dummy region directly contacts the substrate.

16. The OLED display of claim 14, further comprising an insulating layer interposed between the electrode and the substrate, wherein a portion of the insulating layer is formed in the dummy region.

17. The OLED display of claim 16, wherein the portion of the insulating layer is discontinuous.

18. The OLED display of claim 14, wherein a second portion of the electrode formed in the dummy region does not contact the substrate.

19. The OLED display of claim 14, wherein a plurality of the photo sensors are formed at a plurality of positions on the substrate.

20. The OLED display of claim 14, further comprising a reflective layer formed on a second surface of the substrate, wherein the first and second surfaces are opposing each other.
